(19) United States
(12) Patent Application Publication
(10) Pub. No.: US 2023/0055173 A1
(43) Pub. Date: Feb. 23, 2023

(54) METHOD AND DEVICE FOR IMPROVING CURRENT TRANSMISSION RELIABILITY

(71) Applicant: Dongguan Yaosheng Auto Parts Co., Ltd., Dongguan (CN)

(72) Inventors: Jiwu SUN, DONGGUAN (CN); Xin ZHANG, DONGGUAN (CN); Junwei LIANG, DONGGUAN (CN)

(21) Appl. No.: 17/477,399

(22) Filed: Sep. 16, 2021

(30) Foreign Application Priority Data
Aug. 13, 2021 (CN) 202110928383.9

(51) Int. Cl. G01R 31/08; H02J 13/00

(52) U.S. Cl. CPC G01R 31/085; H02J 13/00002

(57) ABSTRACT

A method and a device for improving current transmission reliability are provided. The method includes: selecting effective points; performing technical measurement; generating a threshold: generating a critical abnormal alarm time threshold t₁, generating a critical defect alarm time threshold t₂, and generating a non-critical abnormal electric leakage threshold t₃; and generating a necessary remaining life number Δt₂₁, wherein Δt₂₁=t₂−t₁. By judging whether a current carrying capacity passing through an electric transmission line portion at a certain time exceeds an allowable current carrying capacity, the alarm time threshold t₁ is far lower than 20%, an alarm is capable of being given for an abnormal situation in time, and a necessary remaining life of an electric device or system can be predicted by randomly measuring an input current I_{in i}, an output current I_{out i}, and errors of input and output currents, so that cross liability is avoided.

### CROSS-REFERENCE TO RELATED APPLICATIONS

This application claims foreign priority of Chinese Patent Application No. 202110928383.9 with a filing date of Aug. 13, 2021 in the China National Intellectual Property Administration, the disclosures of all of which are hereby incorporated by reference.

### TECHNICAL FIELD

The present invention relates to a method and a device for improving current transmission reliability, and more particularly, to a method and a device for improving civil current transmission reliability for preventing houses from being destroyed.

### BACKGROUND

Current transmission refers to an electric current (at a current density before conversion) passing through a field. With the rapid development of the national economy and the improvement of people's living standards with each passing year, the consumption of various electric devices has been increased sharply. Electric fire accidents have also been soared, ranking first among all kinds of fires. If electric leakage occurs during current transmission, it is easy to cause damage to the electric devices and even fire, which leads to major accidents such as house destruction, casualties and so on, thus causing huge losses to the national economy and people's lives and property.

In the prior art, Chinese patent No. CN201710533497.7 discloses an “online insulating monitoring-type resistive device for monitoring and detecting electric leakage electrical fire”, which monitors and detects the electric leakage electrical fire through a current detection unit, a current digital filtering unit, a voltage detection unit, a voltage digital filtering unit, a signal separation unit, a display unit, an alarm unit and a monitoring module, and a system structure is too complicated.

Chinese patent No. CN201910419440.3 discloses “a method for preventing false alarm of electric leakage”, it is unscientific to set an alarm threshold to be 20% in the patent. For example, for places with high requirements on a safety level of protection and early warning, an excessively high alarm threshold cannot give an alarm for abnormal situations in time, which will delay a maintenance progress and cause unnecessary losses.

In the prior art, a remaining service life of an electric device or system cannot be predicted, and there is also a technical problem of cross liability caused by overlapping detection methods or data, thus having poor user experience.

### SUMMARY

The present invention aims to provide a method and a device for improving current transmission reliability, so as to solve technical problems of an excessively high alarm threshold, an unpredicted remaining life of an electric device or system, an easily caused cross liability in the prior art. The technical solutions used in the present invention to solve the technical problems are as follows.

A method for improving current transmission reliability includes:

step S100: selecting effective points: respectively selecting an input current effective point Iᵢₙ and an output current effective point Iₒᵤₜ at two ends of a hidden portion of an electric transmission line;

step S200: performing technical measurement: performing technical measurement on the effective points Iᵢₙ and Iₒᵤₜ selected in the step S100;

step S300: generating a threshold: generating a threshold according to measurement results in the step S200, including:

step S301: generating a critical abnormal alarm time threshold t₁,

step S302: generating a critical defect alarm time threshold t₂,

step S303: generating a non-critical abnormal electric leakage threshold t₃;

step S400: randomly measuring an input current I_{in i} and an output current I_{out i} at the hidden portion of the electric transmission line;

step S500: randomly measuring an error δ_{in 1} of the input current I_{in i} and an error δ_{out 2} of the output current I_{out i} at the hidden portion of the electric transmission line; and

step S600: judging values of I_{in i}−I_{out i} and δ_{in 1}+δ_{out 2},

If I_{in i}−I_{out i} is greater than in δ_{in 1}+δ_{out 2}, [formula 1]

generating a necessary remaining life number Δt₂₁, wherein Δt₂₁=t₂−t₁. [formula 2]

The further technical solution of the present invention further includes that: in the step S301, a judgment standard of the critical abnormal alarm time threshold t₁ is that: if a current carrying capacity passing through an electric transmission line portion at a certain time exceeds an allowable current carrying capacity, then the time is the critical abnormal alarm time threshold t₁.

Further, in the step S302, a calculation formula of the critical defect alarm time threshold t₂ is: t₂=t₁(1+b) [formula 3]

in the formula 3, t₁ is the critical abnormal alarm time threshold.

Further, in the step S303, a representation formula of the non-critical abnormal electric leakage threshold t₃ is that: t₃=I_{in i}−I_{out i}>δ_{in 1}+δ_{out 2} [formula 4]

in the formula 4, the representation means that: at the time of electric leakage, a difference between the input current I_{in i} and the output current I_{out i} at the hidden portion of the electric transmission line randomly measured is greater than a sum of the error δ_{in i} of the input current I_{in i} and the error δ_{out 2} of the output current I_{out i} at the hidden portion of the electric transmission line randomly measured; and

the time is the non-critical abnormal electric leakage threshold t₃.

Further, in the step S600, the generating the necessary remaining life number Δt₂₁ further includes: counting the necessary remaining life number Δt₂₁ obtained according to the formula 2 to generate (μ₂₁, σ₂₁), and obtaining that the necessary remaining life number Δt₂₁ is (μ₂₁−Kσ₂₁) [formula 5]

in the formula 5, K represents a standard deviation coefficient of normal distribution of Δt₂₁, and a value of K ranges from 1 to 6;

σ₂₁ represents a variance of the necessary remaining life number Δt₂₁; and

μ₂₁ represents a true value of the necessary remaining life number Δt₂₁.

The present invention further provides a device for improving current transmission reliability, which includes:

a central processing unit;

an input current detection module configured for detecting an input current I_{in i} at a hidden portion of an electric transmission line randomly measured;

an output current detection module configured for detecting an output current I_{out i} at the hidden portion of the electric transmission line randomly measured;

a first sensor configured for feeding back the input current detected by the input current detection module to the central processing unit;

a second sensor configured for feeding back the output current detected by the output current detection module to the central processing unit;

a first alarm device configured for, when the input current I_{in i} or the output current I_{out i} exceeds the allowable current carrying capacity, giving an alarm under control of the central processing unit; and

a second alarm device configured for, in a case of the critical abnormal alarm time threshold t₁, if the critical defect alarm time threshold t₂ satisfies a formula t₂=t₁(1+b), giving an alarm under control of the central processing unit, wherein a value of b is selected based on a line type of the electric transmission line and LSL to USL curves, a is a standard deviation in the LSL to USL curves, and the value of b ranges from 0.75σ to 2.75σ.

According to the first technical solution of the present invention, in the present invention, by judging whether the current carrying capacity passing through the electric transmission line portion at a certain time exceeds the allowable current carrying capacity, if the current carrying capacity exceeds the allowable current carrying capacity, the time is the critical abnormal alarm time threshold t₁, compared with the prior art, the alarm time threshold t₁ is far lower than 20%, which is more scientific, and an alarm is capable of being given for an abnormal situation in time, which is convenient for quick maintenance to reduce unnecessary losses.

According to the second technical solution of the present invention, since the necessary remaining life number Δt₂₁ is determined by the critical defect alarm time threshold t₂ and the critical abnormal alarm time threshold t₁, which is related to the line type of the electric transmission line and the LSL to USL curves, the present invention can predict the necessary remaining life of the electric device or system by randomly measuring the input current I_{in i}, the output current I_{out i} and the errors of the input and output currents.

According to the third technical solution of the present invention, in the device of the present invention, the input current detection module, the output current detection module, the first sensor, the second sensor, the first alarm device and the second alarm device all work independently and do not affect each other, so that there is no technical problem of cross liability caused by overlapping detection methods or data.

According to the fourth technical solution of the present invention, the present invention has a simple structure and a convenient and effective detection method, better improves civil current transmission reliability, and improves user experience.

### BRIEF DESCRIPTION OF THE DRAWINGS

FIG. 1 is a flow chart of a method for improving current transmission reliability in an embodiment of the present invention;

FIG. 2 is a schematic diagram of a principle of preventing current transmission in a critical state in an embodiment of the present invention;

FIG. 3 is a schematic diagram of a defect alarm time threshold t2 in an embodiment of the present invention;

FIG. 4 is a schematic diagram of a principle of preventing current transmission in a non-critical state in an embodiment of the present invention; and

FIG. 5 is a structure block diagram of a device for improving current transmission reliability in an embodiment of the present invention.

### DETAILED DESCRIPTION

In order to make the above objectives, features and advantages of the present invention clearer and more understandable, the specific embodiments of the present invention are described in detail hereinafter with reference to the accompanying drawings. In the following description, many specific details are explained so as to fully understand the present invention. However, the present invention can be implemented in many other ways different from those described herein, and those skilled in the art can make similar improvements without violating the connotation of the present invention, so that the present invention is not limited by the specific embodiments disclosed below.

In the description of the present invention, it shall be understood that the orientation or position relationship indicated by the terms “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “anticlockwise”, “axial”, “radial”, “circumferential”, and the like is based on the orientation or position relationship shown in the accompanying drawings, it is only for the convenience of description of the present invention and simplification of the description, and it is not to indicate or imply that the indicated device or element must have a specific orientation, and be constructed and operated in a specific orientation. Therefore, the terms shall not be understood as limiting the present invention.

Moreover, the terms “first” and “second” are used for descriptive purposes only and cannot be understood as indicating or implying relative importance, or implicitly indicating the number of technical features indicated thereby. Thus, the features defined by “first” and “second” may explicitly or implicitly include one or more features. In the description of the present invention, the meaning of “multiple” is at least two, such as two, three, and so on, unless otherwise specifically defined.

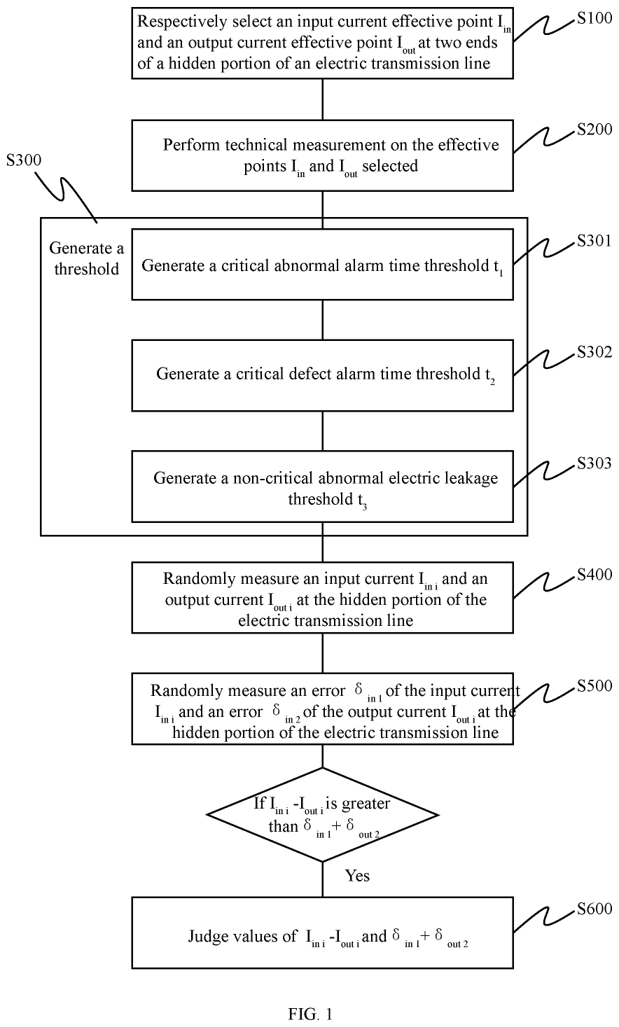

With reference to FIG. 1 to FIG. 5, the present invention provides a method for improving current transmission reliability, which includes:

step S100: selecting effective points: respectively selecting an input current effective point Iᵢₙ and an output current effective point Iₒᵤₜ at two ends of a hidden portion of an electric transmission line, for example, the input current effective point Iᵢₙ may be selected at an input end of a live wire of a hidden project and the output current effective point Iₒᵤₜ may be selected at an output end of the live wire;

step S200: performing technical measurement: performing technical measurement on the effective points Iᵢₙ and Iₒᵤₜ selected in the step S100, wherein in the present invention, the technical measurement may refer to respectively measuring current values or voltage values of the effective points Iᵢₙ and Iₒᵤₜ, and usually refers to measuring the current values;

step S300: generating a threshold: generating a threshold according to measurement results in the step S200, including:

step S301: generating a critical abnormal alarm time threshold t₁,

step S302: generating a critical defect alarm time threshold t₂,

step S303: generating a non-critical abnormal electric leakage threshold t₃;

step S400: randomly measuring an input current I_{in i} and an output current I_{out i} at the hidden portion of the electric transmission line;

step S500: randomly measuring an error δ_{in 1} of the input current I_{in i} and an error δ_{out 2} of the output current I_{out i} at the hidden portion of the electric transmission line; and

step S600: judging values of I_{in i}−I_{out i} and δ_{in 1}+δ_{out 2}, if I_{in i}−I_{out i} is greater than δ_{in 1}+δ_{out 2}, [formula 1];

generating a necessary remaining life number Δt₂₁, wherein Δt₂₁=t₂−t₁. [formula 2]

In the step S301, a judgment standard of the critical abnormal alarm time threshold t₁ is that: if a current carrying capacity passing through an electric transmission line portion at a certain time exceeds an allowable current carrying capacity, then the time is the critical abnormal alarm time threshold t₁. In the present invention, by judging whether the current carrying capacity passing through the electric transmission line portion at a certain time exceeds the allowable current carrying capacity, if the current carrying capacity exceeds the allowable current carrying capacity, the time is the critical abnormal alarm time threshold t₁, compared with the prior art, the alarm time threshold t₁ is far lower than 20%, which is more scientific, and an alarm is capable of being given for an abnormal situation in time, which is convenient for trouble clearing to reduce unnecessary losses.

In the step S302, a calculation formula of the critical defect alarm time threshold t₂ is:

t₂=t₁(1+b) [formula 3]

in the formula 3, t1 is the critical abnormal alarm time threshold; and a value of b is selected based on a line type of the electric transmission line and LSL to USL curves, a is a standard deviation in the LSL to USL curves, and the value of b is 0.75σ to 2.75σ.

It can be seen from the formula 2 and the formula 3 that, the necessary remaining life number Δt₂₁ is determined by the critical defect alarm time threshold t₂ and the critical abnormal alarm time threshold t₁, which is related to the line type of the electric transmission line and the LSL to USL curves, and the present invention can predict the necessary remaining life of the electric device or system by randomly measuring the input current I_{in i}, the output current I_{out i} and the errors of the input and output currents.

In the step S303, a representation formula of the non-critical abnormal electric leakage threshold t₃ is that: t₃=I_{in i}−I_{out i}>δ_{in 1}+δ_{out 2} [formula 4]

in the above formula 4, the representation means that: at the time of electric leakage, a difference between the input current I_{in i} and the output current I_{out i} at the hidden portion of the electric transmission line randomly measured is greater than a sum of the error δ_{in 1} of the input current I_{in i} and the error δ_{out 2} of the output current I_{out i} at the hidden portion of the electric transmission line randomly measured; and

the time is the non-critical abnormal electric leakage threshold t₃.

When the electric leakage occurs, the non-critical abnormal electric leakage threshold t₃ may be reached, and the non-critical abnormal electric leakage threshold t₃ is a precondition for generating the necessary remaining life number Δt₂₁.

In the step S600, the generating the necessary remaining life number Δt₂₁ further includes: counting the necessary remaining life number Δt₂₁ obtained according to the formula 2 to generate (μ₂₁, σ₂₁), and obtaining that the necessary remaining life number Δt₂₁ is (μ₂₁−Kσ₂₁) [formula 5]

in the above formula 5, K represents a standard deviation coefficient of normal distribution of Δt₂₁, and a value of K ranges from 1 to 6;

σ₂₁ represents a variance of the necessary remaining life number Δt₂₁; and

μ₂₁ represents a true value of the necessary remaining life number Δt21.

The present invention further provides a device for improving current transmission reliability, which includes:

a central processing unit;

an input current detection module configured for detecting an input current I_{in i} at a hidden portion of an electric transmission line randomly measured;

an output current detection module configured for detecting an output current I_{out i} at the hidden portion of the electric transmission line randomly measured;

a first sensor configured for feeding back the input current detected by the input current detection module to the central processing unit;

a second sensor configured for feeding back the output current detected by the output current detection module to the central processing unit;

a first alarm device configured for, when the input current I_{in i} or the output current I_{out i} exceeds the allowable current carrying capacity, giving an alarm under control of the central processing unit; and

a second alarm device configured for, in a case of the critical abnormal alarm time threshold t₁, if the critical defect alarm time threshold t₂ satisfies a formula t₂=t₁(1+b), giving an alarm under control of the central processing unit, wherein a value of b is selected based on a line type of the electric transmission line and LSL to USL curves, σ is a standard deviation in the LSL to USL curves, and the value of b ranges from 0.75σ to 2.75σ.

In the device of the present invention, the input current detection module, the output current detection module, the first sensor, the second sensor, the first alarm device and the second alarm device all work independently and do not affect each other, so that there is no technical problem of cross liability caused by overlapping detection methods or data.

### Embodiment 1

Electricity consumption of a certain department of an enterprise in Dongguan, Guangdong is often in a critical state, and power cut inside and outside a tube often occurs, which has affected the production and life of the enterprise. Specific steps for quantifying a necessary remaining life by a method in the embodiment are as follows.

1. Selection of Effective Points

As shown in FIG. 2, main switch outlets of a certain department are selected as the effective points.

2. Performance of Technical Measurement

A clip-on ammeter of ZOYI ZT-QB9 is used to simultaneously perform technical measurement on selected effective points of an induced current of a 10 square copper core according to a Chinese national standard GB/T 4706.1-2005. In the embodiment, the induced current is measured through the clip-on ammeter.

TABLE 1
Chinese national standard GB/T 4706.1-2005

| | |
|---|---|
| Allowable long-term load current of 2.5 square copper core | 16 A to 25 A |
| Allowable long-term load current of 10.0 square copper core | 50 A to 63 A |

3. Generation of Threshold

According to the Chinese national standard GB/T 4706.1-2005, values of the allowable long-term load current of the 10 square copper core are shown in Table 2.

Core numbers and values of allowable long-term
load current of copper core

| | | Allowable current | | |
|---|---|---|---|---|
| Cross section | Load power | carrying capacity (A) | | |
| of copper | (KW) = voltage | Single-core | Twin-core | Three-core |
| core (mm²) | * current | cable | cable | cable |
| 10 | | 63 | 56 | 50 |

A single-core cable with a cross section area of 10 mm² is taken as an example, which has an allowable current carrying capacity of 63 A.

When t₁=63 A, a critical abnormal alarm time threshold t₁ is generated (when t₁>63 A, the time is an abnormal alarm time).

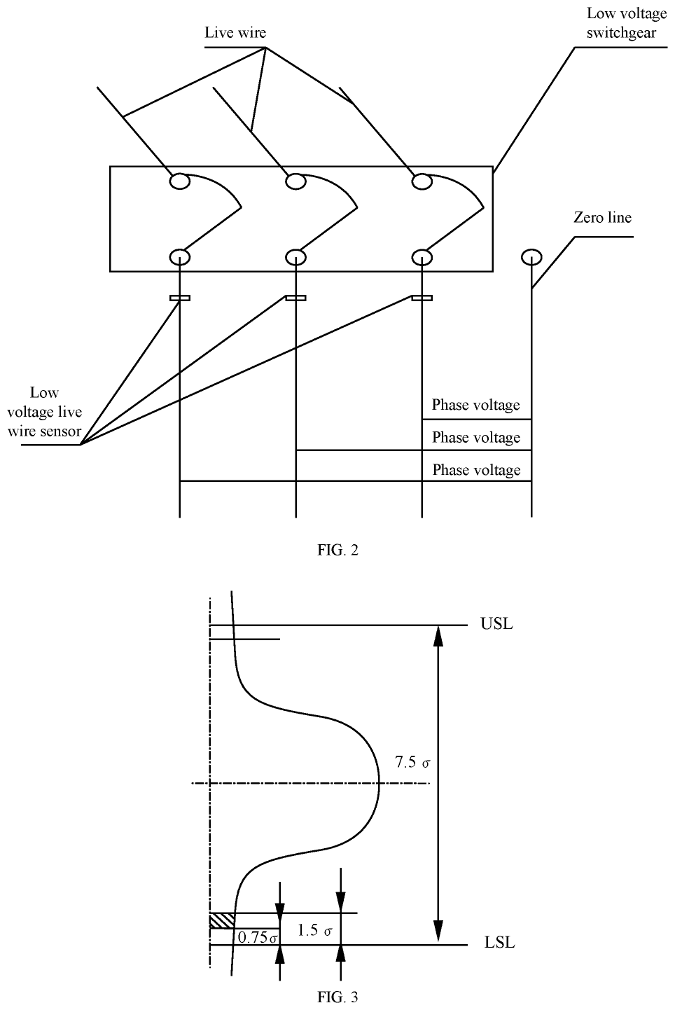

According to LSL to USL curves in FIG. 3 and Table 3, t₂=1.2 t₁=75 A, and at the time, a critical defect alarm time threshold t₂ is generated (when t₂>75 A, the time is a defect alarm time).

TABLE 3
Safe current carrying capacity comparison table of overhead line

| | Temperature | | | | |
|---|---|---|---|---|---|
| | 35° C. | 40° C. | 45° C. | 50° C. | 55° C. |
| Line model | Current carrying capacity/A | | | | |
| LJ-16 | 93 | 84 | 76 | 66 | 53 |
| LGJ-16 | 97 | 88 | 79 | 68 | 56 |
| LJ-25 | 120 | 109 | 98 | 85 | 69 |
| LGJ-25 | 124 | 112 | 101 | 88 | 71 |
| LJ-35 | 150 | 136 | 123 | 106 | 87 |
| LGJ-35 | 150 | 136 | 123 | 106 | 87 |
| LJ-50 | 190 | 172 | 155 | 134 | 110 |
| LGJ-50 | 195 | 177 | 159 | 138 | 113 |
| LJ-70 | 234 | 212 | 191 | 166 | 135 |
| LGJ-70 | 242 | 220 | 198 | 171 | 140 |
| LJ-95 | 290 | 263 | 237 | 205 | 168 |
| LGJ-95 | 295 | 268 | 241 | 209 | 171 |
| LJ-120 | 330 | 300 | 270 | 234 | 191 |
| LGJ-120 | 335 | 304 | 274 | 237 | 194 |
| LJ-150 | 388 | 353 | 318 | 275 | 255 |
| LGJ-150 | 393 | 357 | 322 | 279 | 227 |
| LJ-180 | 440 | 400 | 360 | 312 | 255 |
| LGJ-185 | 450 | 409 | 369 | 319 | 261 |
| LGJ-240 | 540 | 491 | 442 | 383 | 313 |

4. Generation of Necessary Remaining Life Number Δt₂₁

Under confidence of t₂₁=t₂−t₁, (μ₂₁-3σ₂₁) may be counted based on a “±kσ principle” by ±6σ through a formula Δt₂₁=t₂−t₁ [formula 2] in the embodiment. See Table 4 for details.

TABLE 4
Date table of Δt₂₁ when t₁ = 0 (minutes)

| Serial | | | Serial | | |
|---|---|---|---|---|---|
| number | t₂ | Δt₂₁ = t₂-t₁ | number | t₂ | Δt₂₁ = t₂-t₁ |
| 1 | 33 | 33 | 15 | 43 | 43 |
| 2 | 38 | 38 | 16 | 42 | 42 |
| 3 | 42 | 42 | 17 | 40 | 40 |
| 4 | 35 | 35 | 18 | 37 | 37 |
| 5 | 36 | 36 | 19 | 42 | 42 |
| 6 | 41 | 41 | 20 | 39 | 39 |
| 7 | 37 | 37 | 21 | 41 | 41 |
| 8 | 42 | 42 | 22 | 42 | 42 |
| 9 | 39 | 39 | 23 | 40 | 40 |
| 10 | 42 | 42 | 24 | 37 | 37 |
| 11 | 41 | 41 | 25 | 39 | 39 |
| 12 | 38 | 38 | 26 | 43 | 43 |
| 13 | 44 | 44 | 27 | 42 | 42 |
| 14 | 35 | 35 | | | |

A perfect necessary remaining life number Δt₂₁ is obtained as follows:

σ₂₁=2.86

μ₂₁=39.4

μ₂₁−kσ₂₁

When k=3,

the above formula is 39.4−3×2.86=30.82

Δt₂₁=30.82 minutes≈30 minutes (rounding)

The embodiment solves a problem that a safe remaining life of an alarm current cannot be quantified in the prior art, which means that the current may be predicted statistically to be not failed within 30 minutes. When the current exceeds the abnormal time, the treatment is completed within 30 minutes.

5. Blocking Legislation

In the embodiment, a foreground adopts a form of enterprise WeChat, which solves a blocking legislation problem after the foreground adopts a decentralized distributed ledger mode; and a background adopts a blockchain mode.

### Embodiment 2

An electric leakage phenomenon of a non-critical hidden project occurred in an enterprise in Dongguan, Guangdong, which has constituted a potential safety hazard. Specific steps of giving an alarm to the electric leakage by a method in the embodiment are as follows.

1. Selection of Effective Points

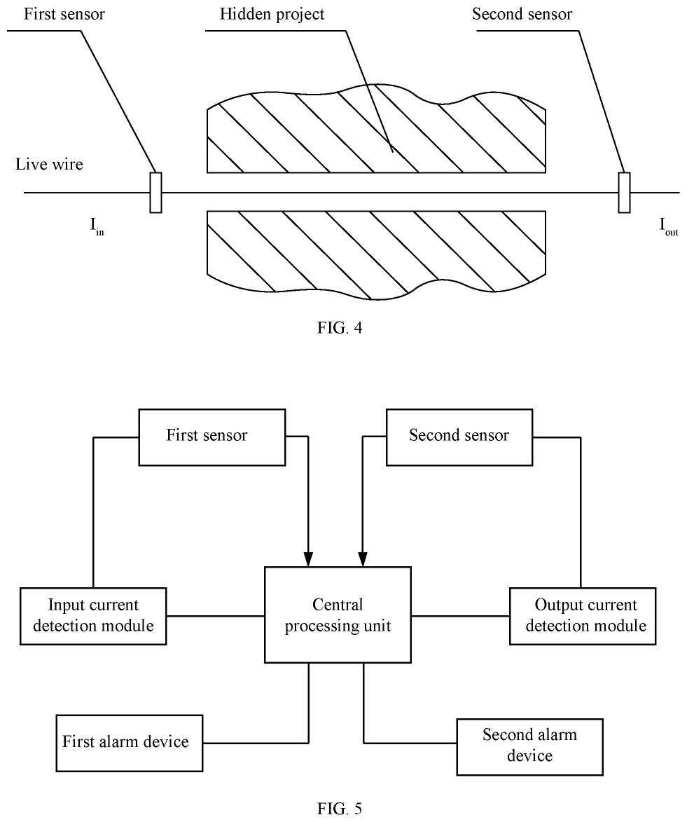

As shown in FIG. 4, effective points are selected outside inlet and outlet ends of a hidden project.

2. Performance of Technical Measurement

A measuring instrument in the embodiment is a clip-on ammeter of ZOYI ZT-QB9, with an instrument precision of ±(2%+3). Technical measurement is simultaneously performed on selected effective points of an induced current of a 2.5 mm² copper wire. In the embodiment, the induced current is measured through the clip-on ammeter. Specific current sample data are shown in Table 5:

TABLE 5
0.1 KW resistance value

| Serial number | Iᵢₙ | Iₒᵤₜ | Iᵢₙ-Iₒᵤₜ |
|---|---|---|---|
| 1 | 0.29 | 0.29 | 0 |
| 2 | 0.28 | 0.30 | −0.02 |
| 3 | 0.24 | 0.28 | −0.04 |
| 4 | 0.24 | 0.24 | 0 |
| 5 | 0.24 | 0.28 | −0.04 |
| 6 | 0.24 | 0.24 | 0 |
| 7 | 0.24 | 0.23 | 0.01 |
| 8 | 0.24 | 0.24 | 0 |
| 9 | 0.24 | 0.24 | 0 |
| 10 | 1.28 | 0.25 | 1.03 |
| 11 | 0.24 | 0.24 | 0 |
| 12 | 0.24 | 0.24 | 0 |
| 13 | 0.24 | 0.24 | 0 |
| 14 | 0.24 | 0.24 | 0 |
| 15 | 0.24 | 0.24 | 0 |
| 16 | 0.24 | 0.24 | 0 |
| 17 | 0.24 | 0.24 | 0 |
| 18 | 0.24 | 0.24 | 0 |
| 19 | 0.24 | 0.24 | 0 |
| 20 | 0.28 | 0.28 | 0 |
| 21 | 0.28 | 0.28 | 0 |
| 22 | 0.24 | 0.28 | −0.04 |
| 23 | 0.29 | 0.29 | 0 |
| 24 | 0.28 | 0.28 | 0 |
| 25 | 0.28 | 0.28 | 0 |

In a case of electric leakage:

when t₃=I_{in i}−I_{out i}>δ_{in 1}+δ_{out 2}

I_{in i}−I_{out i}=1.28−0.25−1.03

δ_{in 1}+δ_{out 2}=(1.28×2%+0.03)+(0.25×2%+0.03)=0.0906

1.03>0.0906

An alarm of electric leakage is given at t₃.

In the embodiment, taking measurement of 0.1 KW resistance value as an example, in a case of electric leakage, an alarm should be given in time, and countermeasures should be taken.

The above embodiments only express several embodiments of the present invention, and the descriptions thereof are specific and detailed, but they cannot be understood as limiting the scope of protection of the present invention. It shall be pointed out that those of ordinary skills in the art may further make several modifications and improvements without departing from the concept of the present invention, and these modifications and improvements all fall within the scope of protection of the present invention. Therefore, the scope of protection of the present invention shall be subject to the appended claims.

What is claimed is:

1. A method for improving current transmission reliability, comprising:
step S100: selecting effective points: respectively selecting an input current effective point Iᵢₙ and an output current effective point Iₒᵤₜ at two ends of a hidden portion of an electric transmission line;
step S200: performing technical measurement: performing technical measurement on the effective points Iᵢₙ and Iₒᵤₜ selected in the step S100;
step S300: generating a threshold: generating a threshold according to measurement results in the step S200, comprising:
step S301: generating a critical abnormal alarm time threshold t₁,
step S302: generating a critical defect alarm time threshold t₂,
step S303: generating a non-critical abnormal electric leakage threshold t₃;
step S400: randomly measuring an input current I_{in i} and an output current I_{out i} at the hidden portion of the electric transmission line;
step S500: randomly measuring an error δ_{in 1} of the input current I_{in i} and an error δ_{out 2} of the output current I_{out i} at the hidden portion of the electric transmission line; and
step S600: judging values of I_{in i}−I_{out i} and δ_{in 1}+δ_{out 2},
if I_{in i}−I_{out i} is greater than δ_{in 1}+δ_{out 2}, [formula 1]
generating a necessary remaining life number Δt₂₁, wherein Δt₂₁=t₂−t₁. [formula 2]

2. The method according to claim 1, wherein in the step S301, a judgment standard of the critical abnormal alarm time threshold t₁ is that: if a current carrying capacity passing through an electric transmission line portion at a certain time exceeds an allowable current carrying capacity, then the time is the critical abnormal alarm time threshold t₁.

3. The method according to claim 1, wherein in the step S302, a calculation formula of the critical defect alarm time threshold t₂ is: t₂=t₁(1+b) [formula 3]
in the formula 3, t₁ is the critical abnormal alarm time threshold; and
a value of b is selected based on a line type of the electric transmission line and LSL to USL curves, σ is a standard deviation in the LSL to USL curves, and the value of b is 0.75σ to 2.75σ.

4. The method according to claim 1, wherein in the step S303, a representation formula of the non-critical abnormal electric leakage threshold t₃ is that: t₃=I_{in i}−I_{out i}>δ_{in 1}+δ_{out 2} [formula 4]
in the formula 4, the representation means that: at the time of electric leakage, a difference between the input current I_{in i} and the output current I_{out i} at the hidden portion of the electric transmission line randomly measured is greater than a sum of the error δ_{in 1} of the input current I_{in i} and the error δ_{out 2} of the output current I_{out i} at the hidden portion of the electric transmission line randomly measured; and
the time is the non-critical abnormal electric leakage threshold t₃.

5. The method according to claim 1, wherein in the step S600, the generating the necessary remaining life number Δt₂₁ further comprises: counting the necessary remaining life number Δt₂₁ obtained according to the formula 2 to generate (μ₂₁, σ₂₁), and obtaining that the necessary remaining life number Δt₂₁ is (μ₂₁−Kσ₂₁) [formula 5]
in the formula 5, K represents a standard deviation coefficient of normal distribution of Δt₂₁, and a value of K ranges from 1 to 6;
σ₂₁ represents a variance of the necessary remaining life number Δt₂₁; and
μ₂₁ represents a true value of the necessary remaining life number Δt₂₁.

6. A device for improving current transmission reliability, comprising:
a central processing unit;
an input current detection module configured for detecting an input current I_{in i} at a hidden portion of an electric transmission line randomly measured;
an output current detection module configured for detecting an output current I_{out i} at the hidden portion of the electric transmission line randomly measured;
a first sensor configured for feeding back the input current detected by the input current detection module to the central processing unit;
a second sensor configured for feeding back the output current detected by the output current detection module to the central processing unit;
a first alarm device configured for, when the input current I_{in i} or the output current I_{out i} exceeds the allowable current carrying capacity, giving an alarm under control of the central processing unit; and
a second alarm device configured for, in a case of the critical abnormal alarm time threshold t₁, if the critical defect alarm time threshold t₂ satisfies a formula t₂=t₁(1+b), giving an alarm under control of the central processing unit, wherein a value of b is selected based on a line type of the electric transmission line and LSL to USL curves, σ is a standard deviation in the LSL to USL curves, and the value of b ranges from 0.75σ to 2.75 σ.
